(19) United States
(12) Patent Application Publication
(10) Pub. No.: US 2021/0391693 A1
(43) Pub. Date: Dec. 16, 2021

(54) STRUCTURED ILLUMINATION DEVICES

(71) Applicant: ams Sensors Asia Pte. Ltd., Singapore (SG)

(72) Inventor: James Eilertsen, Zurich (CH)

(21) Appl. No.: 17/282,540

(22) PCT Filed: Oct. 21, 2019
(86) PCT No.: PCT/SG2019/050522

§ 371 Date: Apr. 2, 2021

Related U.S. Application Data
(60) Provisional application No. 62/748,738, filed on Oct. 22, 2018.

(51) Int. Cl. H01S 5/183; G02B 3/00; H01S 5/026; G01B 11/25; H04N 13/254; G06K 9/00

(52) U.S. Cl. CPC H01S 5/18388; G02B 3/0006; G06K 9/00255; G01B 11/25; H04N 13/254; H01S 5/026

(57) ABSTRACT

An illumination device includes an emission layer including a semiconductor-based light emitter; and an optical layer disposed on the emission layer. The optical layer includes an optical element, such as a lens, at least partially aligned with the semi-conductor-based light emitter. The optical layer is formed of a material having a negative coefficient of thermal expansion (CTE). For instance, the semiconductor-based light emitter is configured to emit light at a wavelength λ, and in which a pitch p of the MLA, a thickness z of the optical layer, and the wavelength λ satisfy a predefined relationship.

### BACKGROUND

Structured light is light having a specific pattern. Illumination devices that produce structured light can be used for three-dimensional (3-D) imaging, which has applications in diverse fields such as autonomous vehicles and facial recognition.

### SUMMARY

In an aspect, an illumination device includes an emission layer including a semiconductor-based light emitter; and an optical layer disposed on the emission layer. The optical layer includes an optical element at least partially aligned with the semiconductor-based light emitter. The optical layer is formed of a material having a negative coefficient of thermal expansion (CTE).

Embodiments can include one or more of the following features.

The optical element and the optical layer may be monolithic. For example, they are in the form of a monolithic layer.

The optical element includes a lens.

The optical layer includes a micro-lens array (MLA) including multiple lenses.

The MLA and the optical layer may be monolithic. For example, they are in the form of a monolithic layer.

The emission layer includes multiple semiconductor-based light emitters, each of one or more lenses of the MLA being at least partially aligned with a corresponding semiconductor-based light emitter.

The semiconductor-based light emitter is configured to emit light at a wavelength λ, and in which a pitch p of the MLA, a thickness z of the optical layer, and the wavelength λ satisfy a predefined relationship.

The pitch p, the thickness z, and the wavelength λ satisfy the predefined relationship z=p\hat{ }2/λ.

Responsive to a change in temperature, the semiconductor-based light emitter is configured to emit light at a second wavelength λ2 and the optical layer is configured to have a thickness z2, and in which the pitch p, the second thickness z2, and the wavelength λ2 satisfy the predefined relationship.

The semiconductor-based light emitter includes a semiconductor laser, e.g., a vertical-cavity surface-emitting laser (VCSEL).

The monolithic structure of the MLA and optical layer may, in some cases, prevent the MLA from becoming detached from the optical layer. This may, for example, prevent a person from being directly exposed to laser light.

The optical layer includes a glass, a polymer, or a composite material having a negative CTE.

The optical layer includes a wafer bonded to the emission layer, the wafer being formed of the material having a negative CTE, and the wafer including the optical element.

The optical layer includes a film disposed on the emission layer, the film being formed of the material having a negative CTE, and the optical element being formed in the film.

The material of the optical layer has a CTE of between −1×10−7 and −1×10−5° C.−1.

The material of the optical layer has a negative CTE in a direction perpendicular to the plane of the optical layer.

The illumination device forms part of a three-dimensional (3-D) imaging system, e.g., a 3-D imaging system for a vehicle or for a mobile computing device.

In an aspect, a method of making an illumination device includes disposing an optical layer on an emission layer including a semiconductor-based light emitter, including at least partially aligning an optical element of the optical layer with the semiconductor-based light emitter, the optical layer being formed of a material having a negative CTE.

Embodiments can include one or more of the following features.

Disposing the optical layer on the emission layer includes bonding a wafer to the emission layer, the wafer being formed of the material having a negative CTE, and the wafer including the optical element.

Bonding a wafer to the emission layer includes bonding a glass wafer having a negative CTE to the emission layer.

Disposing the optical layer on the emission layer includes depositing a layer of the material having a negative CTE onto the emission layer; and forming the optical element in the deposited layer.

Monolithically incorporating the optical element with the optical layer. For example, forming the optical element and the optical layer as a monolithic layer.

Forming the optical element using a microfabrication technique, such as photolithography, for example, forming the optical element onto one side of the optical layer by such a microfabrication technique.

Depositing a layer of the material having a negative CTE onto the emission layer includes depositing a polymer having a negative CIE onto the emission layer.

The method includes forming the emission layer.

The emission layer includes a VCSEL.

The optical element includes a lens.

The optical layer includes an MLA including multiple lenses, and in which disposing the optical layer on the emission layer includes at least partially aligning each of one or more of the lenses of the MLA with a corresponding semiconductor-based light emitter.

The semiconductor-based light emitter is configured to emit light at a wavelength λ. Disposing the optical layer on the emission layer includes disposing the optical layer in a thickness z that satisfies a predefined relationship among the thickness z, a pitch p of the MLA, and the wavelength λ.

Disposing the optical layer on the emission layer includes disposing the optical layer in a thickness z that satisfies the predefined relationship z=p\hat{ }2/λ.

In an aspect, a 3-D imaging system includes an illumination device configured to illuminate an object with a pattern of light, the illumination device including an emission layer including a semiconductor-based light emitter; and an optical layer disposed on the emission layer. The optical layer includes an optical element at least partially aligned with the semiconductor-based light emitter. The optical layer is formed of a material having a negative CTE;

a sensor configured to capture an image of the illuminated object. The 3-D imaging system also includes one or more computing devices configured to determine a 3-D shape of the object based on the captured image.

Embodiments can include one or more of the following features.

The sensor includes a camera.

The one or more computing devices are configured to determine a 3-D mapping of an area based on the captured image.

The one or more computing devices are configured to perform a facial recognition process based on the determined 3-D shape of the object.

The structured illumination devices described here can have one or more of the following advantages. An optical layer formed of a material with a negative coefficient of thermal expansion can contract with increasing temperature, offsetting a wavelength shift induced by the increase in temperature and enabling a high quality structured light output to be maintained.

### BRIEF DESCRIPTION OF DRAWINGS

FIG. 1 is a diagram of a structured light illumination device.

FIGS. 2A and 2B are diagrams of a structured light illumination device.

FIG. 3 is a flow chart.

FIG. 4 is a diagram of a vehicle.

FIGS. 5A and 5B are diagrams of a mobile computing device.

### DETAILED DESCRIPTION

We describe here an illumination device capable of producing structured light, e.g., for three-dimensional (3-D) imaging applications such as mapping or facial recognition. The illumination device described here includes a light emitter and one or more optical elements, such an array of micro-lenses, at least one of which is at least partially aligned with the light emitter. The light emitter is separated from the optical elements by an optical layer that is formed of a material having a negative coefficient of thermal expansion (CTE).

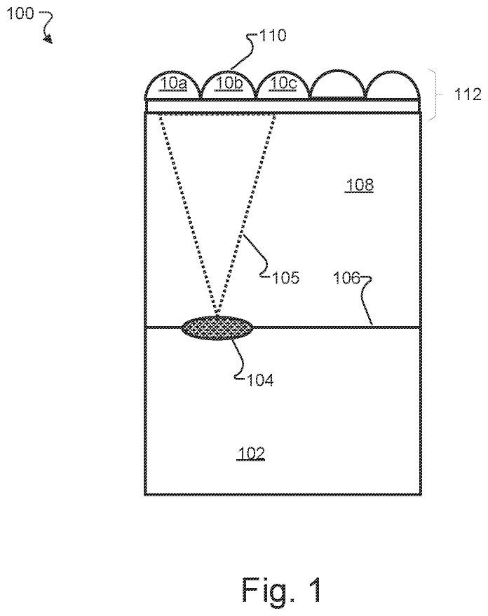

Referring to FIG. 1, a structured light illumination device 100 emits a pattern of light, sometimes referred to as structured light. Structured light can be used for 3-D imaging. For instance, the structured light illumination device 100 can form part of a 3-D imaging system for a vehicle, such as a partially-autonomous or fully-autonomous vehicle. The structured light illumination device 100 can form part of a 3-D imaging system for a mobile computing device, such as a mobile phone, e.g., for facial recognition or mapping of an environment.

The structured light illumination device 100 includes an emission layer 102 that includes a semiconductor-based light emitter 104, such as a semiconductor laser, e.g., a vertical-cavity surface-emitting laser (VCSEL) or a side-emitting semiconductor laser; or a diode, such as a laser diode or a light emitting diode (LED). For instance, the emission layer 102 can be a wafer, such as a silicon wafer, in which the light emitter 104 is fabricated. The light emitter 104 emits light 105 from an emission surface 106 of the emission layer 102. The light can be visible light, infrared light, or ultraviolet light. In some examples, the emission layer 102 can include multiple light emitters 104, e.g., a one-dimensional or two-dimensional array of light emitters 104.

An optical layer 108 is disposed on the emission layer 102. The optical layer 108 can be transparent to the wavelength of light emitted from the light emitter 104. In some examples, the optical layer can be a wafer that is attached to the emission layer 102 by a wafer attachment technique, such as wafer bonding. In some examples, the optical layer can be a thin film that is deposited onto the emission layer 102 by a thin film deposition technique.

The optical layer 108 includes one or more optical elements 110, such as lenses. For instance, as shown in FIG. 1, the optical layer 108 can include an array 112 of multiple optical elements 110 (e.g., multiple lenses), which is sometimes referred to as a micro-lens array (MLA). The structured light emission from the illumination device 100 originates from an interference pattern created by the interference of light propagating from different ones of the optical elements 110 in the MLA 112, enabling the contrast of the structured light to remain generally constant across the far field of the MLA 112, e.g., at least as far as 5 cm, 10 cm, 50 cm, 100 cm, or farther.

The one or more optical elements 110 and the optical layer 108 can be monolithic, where the one or more optical elements 110 are formed onto one side of the optical layer 108 by, for example, a microfabrication process. An example of such a microfabrication process is photolithography. Such a monolithic arrangement has the benefit of improved eye safety in the case that the light emitter 104 is a laser. For example, in some cases, the monolithic structure of the one or more optical elements 110 and the optical layer 108 prevents the one or more optical elements 110 from becoming detached from the optical layer 108 and thus, for example, a person is prevented from direct exposure to the light 105. In other words, the monolithic arrangement discussed here provides improved eye safety because the MLA 112 is less likely to become dislodged from a VCSEL assembly, thereby preventing a user from being directly exposed to a laser beam. It will be appreciated that this monolithic or integrated arrangement, described with reference to FIG. 1, may be applied to subsequent figures.

The MLA 112 can be a one-dimensional array of lenses 110 or a two-dimensional array of lenses 110. The lenses 110 of the MLA 112 can be transmissive micro-lenses or reflective micro-lenses. Transmissive micro-lenses are transparent to at least a portion of the light emitted from the light emitter 104, such that light propagates through the micro-lenses. The transmissive micro-lenses can be diffractive micro-lenses or refractive micro-lenses. For instance, the transmissive micro-lenses can be athermalized micro-lenses or other hybrid lenses. Reflective micro-lenses reflect at least a portion of the light emitted from the light emitter 104. Reflective micro-lenses can have a smooth, curved surface or can be structured with diffractive structures. The micro-lenses can be convex lenses or concave lenses.

At least one of the optical elements 110 is at least partially aligned with the light emitter 104. An optical element that is at least partially aligned with the light emitter 104 is positioned to receive at least some of the light emitted by the light emitter 104. In the example of FIG. 1, three optical elements 10a, 10b, 10c are at least partially aligned with the light emitter 104.

The thickness z of the optical layer 108, the pitch p of the MLA 112, and the wavelength λ of light emitted from the light emitter 104 affect characteristics of the light emitted from the illumination device 100. For instance, when the thickness z, the pitch p, and the wavelength λ satisfy a target relationship, high contrast spots are produced in the emitted light, meaning that structured light is emitted from the illumination device 100. When the thickness z, the pitch p, and the wavelength λ fail to satisfy the relationship, the structured quality of the emitted light can be reduced, e.g., the spots can increase in size or decrease in contrast, and the emitted light can be unsuitable for structured light applications.

The target relationship among the thickness z, the pitch p, and the wavelength λ can be characterized by Equation (1), known as the Lau equation:

$$z = \frac{{p}^{2}}{λ} . \qquad ( 1 )$$

When the thickness z, the pitch p, and the wavelength λ satisfy Equation (1), high contrast spots are produced and usable structured light is emitted from the illumination device. When Equation (1) is not satisfied, the quality of the emitted light can decline.

By satisfying Equation (1), we mean that the values of z, p, and λ are such that Equation (1) is satisfied within a threshold X, i.e.,

$$Z = X \frac{{p}^{2}}{λ} .$$

For instance, Equation (1) can be considered to be satisfied for values of X between 0.95 and 1.05, e.g., between 0.98 and 1.02 or between 0.99 and 1.01. The value of the threshold X can depend on various factors, such as an amount of acceptable loss in contrast or spot size of the emitted light that is appropriate for an intended application of the illumination device 100.

In some examples, such as when the light emitter 104 produces a single wavelength of light, e.g., when the light emitter 104 is a laser, the wavelength λ referred to in Equation (1) is that single wavelength produced by the light emitter 104. In some examples, such as when the light emitter 104 produces multiple wavelengths, the wavelength λ of Equation (1) can be any of the emitted wavelengths, such as a peak wavelength in a spectrum of emitted wavelengths.

The pitch p of the MLA 112 can be between about 5 μm and about 250 μm, e.g., between about 10 μm and about 150 μm.

Further description of the production of structured light from a light emitter and MLA can be found in WO 2016/122404, the contents of which are incorporated here by reference in their entirety.

During operation of the structured light illumination device 100, the light emitter 104 can increase in temperature. For instance, if the optical layer 108 is a poor thermal conductor, the heat generated by light emission cannot be dissipated easily, causing the temperature of the light emitter 104 to rise. An increase in temperature of the light emitter 104 causes the wavelength emitted from the light emitter 104 to increase. In a specific example, the wavelength emitted from a VCSEL can increase by about 0.07 nm/° C. In another specific example, the wavelength emitted from an edge emission device can increase by about 0.35 nm/° C.

To enable the illumination device 100 to continue to satisfy Equation (1) even as the wavelength λ increases, the optical layer 108 can be formed of a material having a negative coefficient of thermal expansion (CTE). A negative CTE material is a material that contracts as temperature increases. This means that a temperature increase, which causes the wavelength λ to increase, will also cause the thickness z of the optical layer 108 to decrease, thereby dynamically repositioning the optical element(s) 110 relative to the light emitter 102 such that Equation (1) remains satisfied.

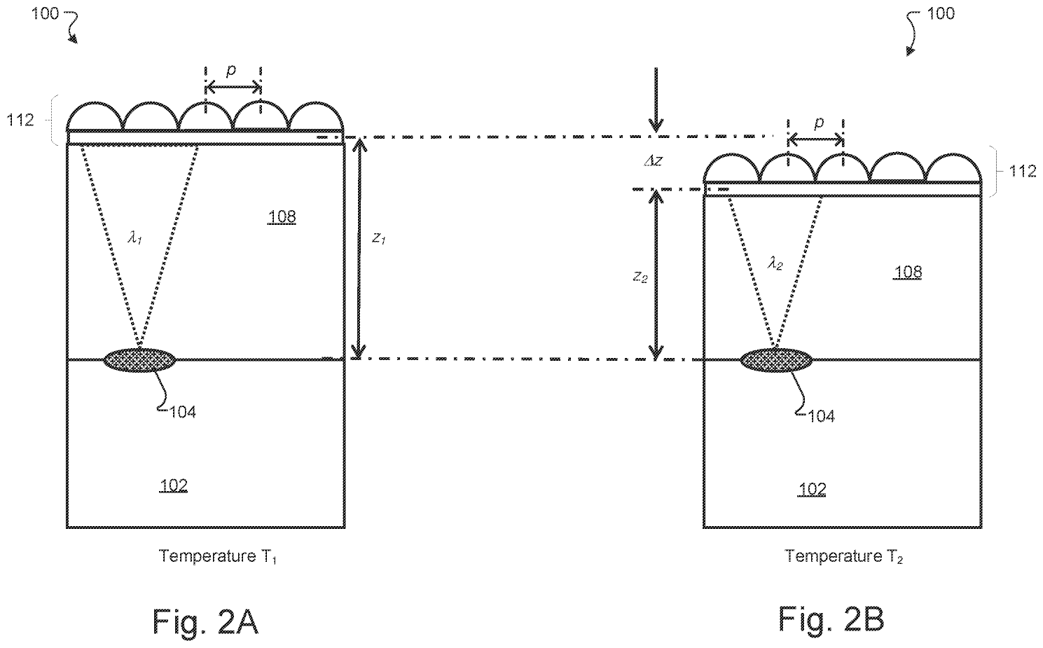

Referring to FIG. 2A, in a specific example, the structured light illumination device 100 includes a VCSEL 104 operating at an initial wavelength λ₁ of 850 nm at an initial temperature of T₁. The VCSEL 104 is characterized by a wavelength shift of 0.07 nm/° C. The optical layer 108 has an initial thickness z₁ of 2.94 mm and the MLA 112 has a pitch p of 50 μm. The optical layer 108 is formed of a material with a CTE of −1×10⁻⁵.

Referring also to FIG. 2B, the VCSEL and optical layer 108 undergo an increase in temperature of 71° C. during operation to a temperature of T₂, causing a wavelength shift of +5 nm, to a shifted wavelength λ₂ of 855 nm. The temperature increase causes the optical layer 108 to contract in thickness by 2.09 μm, to a contracted thickness z₂ of 2.9379 nm (less than the initial thickness z₁ by a difference Δz. The contracted thickness z₂ and the shifted wavelength λ₂ satisfy Equation (1), meaning that the structured nature of the illumination emitted from the illumination device 100 is maintained despite the heat-induced increase in emission wavelength.

By contrast, if the optical layer 108 in the above example were formed of a material with a positive coefficient of thermal expansion, the thickness of the optical layer would increase with increasing temperature. For instance, an optical layer 108 formed of sapphire (a positive CTE material) would increase in thickness of up to 1 μm responsive to the 71° C. increase in temperature. The combination of a +5 nm wavelength shift and an increase in optical layer thickness 108 would cause the heated illumination device 100 to fail to satisfy Equation (1), meaning that the spot size or spot contrast produced from the illumination device would be insufficient for structured light applications.

The optical layer 108 can be formed of any negative CTE material that is substantially transparent to the wavelength emitted by the light emitter 102. For instance, the optical layer 108 can be made of a negative CTE glass material, e.g., a glass ceramic material, a negative CTE polymer, or a composite material (e.g., a composite of a polymer and an inorganic material) with a negative CTE. In some examples, the optical layer 108 can have a CTE of between about −1×10⁻⁷ and about −1×10⁻⁵.

Example materials having a negative CTE include glass ceramics including Li₂O—Al₂O₃—SiO₂, glass ceramics including ZnO—Al₂O₃—SiO₂, glass ceramics including Li₂O and BaO, glass ceramics including Al₂O₃ and BaO, or glass ceramics including Li₂O—Al₂O₃—SiO₂—BaO. For instance, example negative CTE materials are described in U.S. Pat. No. 6,521,556, the contents of which are incorporated here by reference in their entirety.

In some examples, the optical layer 108 can have an isotropic CTE. In some examples, the optical layer 108 can have an anisotropic CTE in which the CTE in the direction perpendicular to the emission surface 106 of the emission layer 102 is negative and the CTE in the direction parallel to the emission surface 106 of the emission layer 102 can be positive or negative. For instance, an optical layer formed of a single crystal material can have an anisotropic CTE.

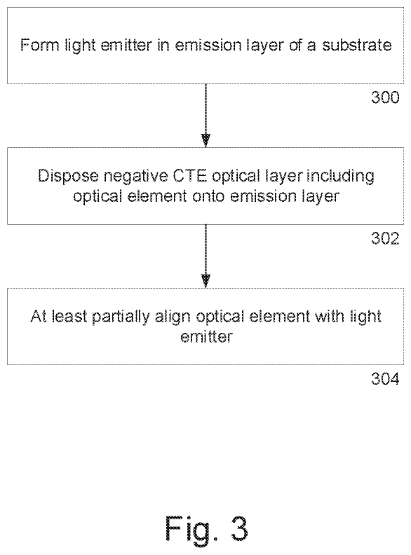

Referring to FIG. 3, to fabricate a structured light illumination device, one or more light emitters, such as VCSELs, side emitting semiconductor lasers, laser diodes, or other types of light emitters, are formed in an emission layer of a substrate, such as a silicon wafer (300). An optical layer formed of a material having a negative CTE is disposed on the emission layer (302). An optical element of the optical layer is at least partially aligned with the light emitter (304). In some examples, the optical layer is a wafer in which the optical element has been previously formed, and the wafer is bonded by a wafer bonding technique to the emission layer. In some examples, the optical layer is deposited as a thin film on the emission layer, and the optical element is formed in the optical layer, e.g., using integrated circuit processing techniques such as lithography and etching.

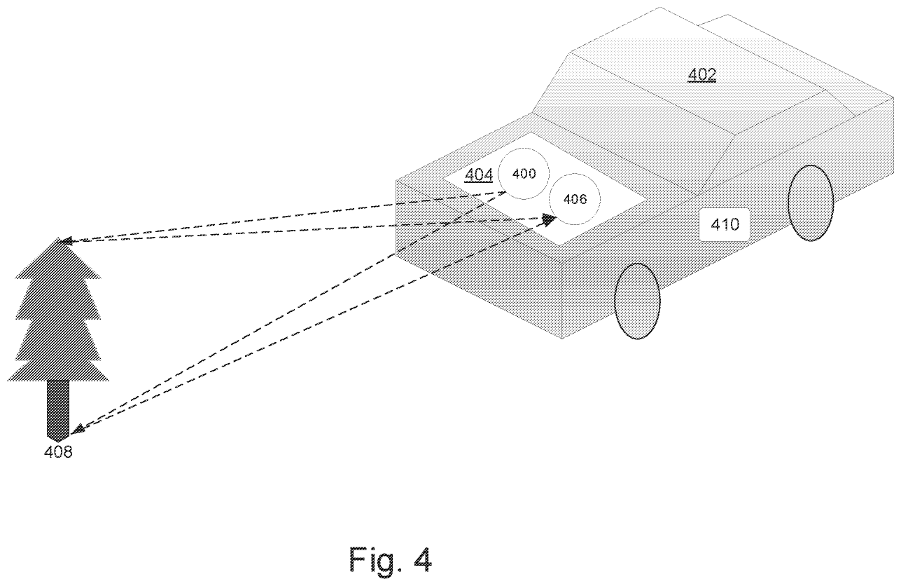

Referring to FIG. 4, in some examples, a structured light illumination device 400 such as the illumination device 100 of FIG. 1 can be mounted on a vehicle 402, such as a partially-autonomous or fully-autonomous vehicle. The vehicle can be a land-based vehicle (as shown), such as a car or truck; an aerial vehicle, such as an unmanned aerial vehicle; or a water-based vehicle, such as a ship or submarine. In the context of the partially- or fully-autonomous vehicle 402, the structured light illumination device 400 can form part of a 3-D imaging system 404 that includes imaging components such as a sensor 406, e.g., a camera. The 3-D imaging system 404 including the structured light illumination device 400 can be used, e.g., for 3-D mapping of the environment of the vehicle 402. For instance, the structured light illumination device 400 can be used to illuminate an object 408, e.g., an object in or near a roadway on which the vehicle 402 is traveling, and the sensor 406 can be used to capture an image of the illuminated object 408. The captured image can be provided to a computing device 410, e.g., including one or more processors, that determines a 3-D shape of the object based on the captured image. By determining the 3-D shapes of various objects, a mapping of an environment of the vehicle can be determined and used to control the partially- or fully-autonomous operation of the vehicle 402.

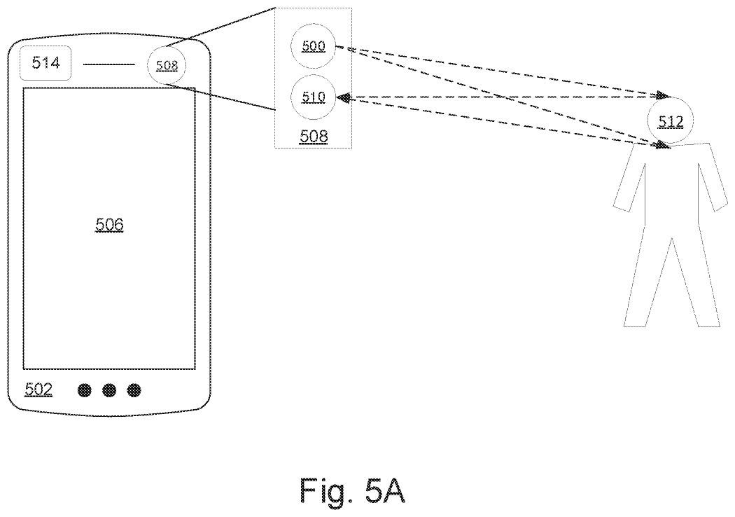

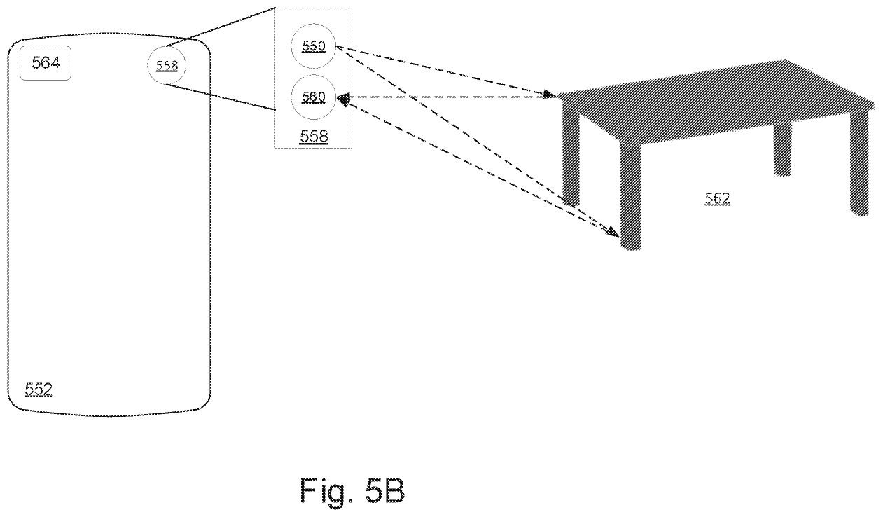

Referring to FIG. 5A, in some examples, a structured light illumination device 500 such as the illumination device 100 of FIG. 1 can be mounted on or incorporated into a front side of a mobile computing device 502, such as a mobile phone, a tablet, or a wearable computing device. The front side of the mobile device 502 is the side of the device that includes a screen 506. The structured light illumination device 500 can be incorporated into a front-side imaging system 508 that includes imaging components such as a sensor 510, e.g., a camera. The front-side imaging system 508 including the structured light illumination device 500 can be used for 3-D imaging applications, e.g., for facial recognition. For instance, the structured light illumination device 500 can be used to illuminate a face 512 of a person, and the sensor 510 can be used to capture an image of the face 512. The captured image can be provided to one or more processors 514, e.g., in the mobile device 502 or remote, such as cloud-based processors. The one or more processors 514 can perform facial recognition processing on the image of the face 512.

Referring to FIG. 5B, in some examples, a structured light illumination device 550 such as the illumination device 100 of FIG. 1 can be mounted on a back side of a mobile computing device 552. The back side is the side of the device opposite the front side, such as the side that does not include a screen. The structured light illumination device 550 can be incorporated into a back-side imaging system 558 that includes imaging components such as a sensor 560, e.g., a camera. The back-side imaging system 558 including the structured light illumination device 550 can be used, e.g., for 3-D imaging applications, e.g., for object recognition or for environmental mapping, such as mapping of a room. For instance, the structured light illumination device 550 can be used to illuminate an object 562 in a room or other environment, and the sensor 560 can be used to capture an image of the object 562. The captured image can be provided to one or more processors 564, e.g., in the mobile device 552 or remote, such as cloud-based processors. The one or more processors 564 can determine a 3-D shape of the object based on the captured image. The determined 3-D shape can be used by the one or more processors 564 to perform object recognition processing, or can be used in combination with determined 3-D shapes of one or more other objects to develop a 3-D mapping of the room.

Structured light illumination devices such as those described here can be incorporated into other devices, including game consoles, distance measuring devices, surveillance devices, and other devices.

A number of embodiments have been described. Nevertheless, it will be understood that various modifications may be made without departing from the spirit and scope of the invention. For example, some of the steps described above may be order independent, and thus can be performed in an order different from that described.

Other implementations are also within the scope of the following claims.

1. An illumination device comprising:
an emission layer including a semiconductor-based light emitter; and
an optical layer disposed on the emission layer, the optical layer including an optical element at least partially aligned with the semiconductor-based light emitter, the optical layer being formed of a material having a negative coefficient of thermal expansion (CTE).

2. The illumination device of claim 1, in which the optical element and the optical layer are monolithic.

3. The illumination device of claim 1, in which the optical element includes a lens.

4. The illumination device of claim 3, in which the optical layer includes a micro-lens array (MLA) comprising multiple lenses.

5. The illumination device of claim 4, in which the emission layer comprises multiple semiconductor-based light emitters, each of one or more lenses of the MLA being at least partially aligned with a corresponding semiconductor-based light emitter.

6. The illumination device of claim 4, in which the semiconductor-based light emitter is configured to emit light at a wavelength λ, and in which a pitch p of the MLA, a thickness z of the optical layer, and the wavelength λ satisfy a predefined relationship.

7. The illumination device of claim 6, in which the pitch p, the thickness z, and the wavelength λ satisfy the predefined relationship
$$z = \frac{{p}^{2}}{λ} .$$

8. The illumination device of claim 6, in which responsive to a change in temperature, the semiconductor-based light emitter is configured to emit light at a second wavelength λ₂ and the optical layer is configured to have a thickness z₂, and in which the pitch p, the second thickness z₂, and the wavelength λ₂ satisfy the predefined relationship.

9. (canceled)

10. The illumination device of claim 1, in which the semiconductor-based light emitter comprises a semiconductor laser; optionally in which the semiconductor laser comprises a vertical-cavity surface-emitting laser (VCSEL).

11. (canceled)

12. The illumination device of claim 1, in which the optical layer comprises one or more of:
a glass having a negative CTE;
a polymer having a negative CTE; and/or
a composite material, the composite material having a negative CTE.

13.-14. (canceled)

15. The illumination device of claim 1, in which the optical layer comprises a wafer bonded to the emission layer, the wafer being formed of the material having a negative CTE, and the wafer including the optical element.

16. The illumination device of claim 1, in which the optical layer comprises a film disposed on the emission layer, the film being formed of the material having a negative CTE, and the optical element being formed in the film.

17. The illumination device of claim 1, in which the material of the optical layer has a CTE of between −1×10⁻⁷ and −1×10⁻⁵° C.⁻¹.

18. The illumination device of claim 1, in which the material of the optical layer has a negative CTE in a direction perpendicular to the plane of the optical layer.

19.-21. (canceled)

22. A method of making an illumination device, comprising:
disposing an optical layer on an emission layer including a semiconductor-based light emitter, including at least partially aligning an optical element of the optical layer with the semiconductor-based light emitter, the optical layer being formed of a material having a negative CTE.

23. The method of claim 22, in which disposing the optical layer on the emission layer comprises bonding a wafer to the emission layer, the wafer being formed of the material having a negative CTE, and the wafer including the optical element.

24. (canceled)

25. The method of claim 22, in which disposing the optical layer on the emission layer comprises:
depositing a layer of the material having a negative CTE onto the emission layer; and
forming the optical element in the deposited layer.

26. (canceled)

27. The method of claim 25, in which the optical element is incorporated with the optical layer by a microfabrication technique; in which the optical element is formed by photolithography.

28.-35. (canceled)

36. A 3-D imaging system comprising:
an illumination device configured to illuminate an object with a pattern of light, the illumination device comprising:
an emission layer including a semiconductor-based light emitter; and
an optical layer disposed on the emission layer, the optical layer including an optical element at least partially aligned with the semiconductor-based light emitter, the optical layer being formed of a material having a negative CTE;
a sensor configured to capture an image of the illuminated object; and
one or more computing devices configured to determine a 3-D shape of the object based on the captured image.

37. (canceled)

38. The 3-D imaging system of claim 36, in which the one or more computing devices are configured to determine a 3-D mapping of an area based on the captured image; and/or
in which the one or more computing devices are configured to perform a facial recognition process based on the determined 3-D shape of the object.

39. (canceled)
